(19) United States
(12) Patent Application Publication
(10) Pub. No.: US 2015/0286251 A1
(43) Pub. Date: Oct. 8, 2015

(54) CASES FOR PORTABLE ELECTRONIC DEVICES

(71) Applicant: Signals IT Ltd., Greater Manchester (GB)

(72) Inventor: Peter EMSLIE, Greater Manchester (GB)

(21) Appl. No.: 14/668,363

(22) Filed: Mar. 25, 2015

(30) Foreign Application Priority Data
Apr. 7, 2014 (GB) 1406224.4

(51) Int. Cl. G06F 1/16; H01B 7/08; H05K 5/02

(52) U.S. Cl. CPC G06F 1/1632; H05K 5/0247; H01B 7/08

(57) ABSTRACT

A case for a portable electronic device comprising a main body portion having a hollow receiving portion adapted, in use, to releasably receive, and engage with, the exterior of the portable electronic device, the main body portion comprising a plug connector adapted, in use, to engage with a power and/or data port of the portable electronic device and a contact pad located on an exterior surface of the case.

### BACKGROUND OF THE INVENTION

This invention relates to cases for portable electronic devices and in particular, to adapters for mounting and charging portable electronic devices.

### BRIEF SUMMARY OF THE INVENTION

It is commonplace nowadays for users of portable electronic devices, such as satellite navigation systems, mobile telephones, laptop computers, tablet computers etc. to charge them in vehicles. For example, courier drivers may be provided with a mobile telephone and a mapping/routing/point of delivery (POD) device, which is held in a charging dock, for example, mounted to the dashboard of a vehicle. In use, a delivery driver may arrive at a destination and remove the portable electronic device so that a customer can sign for a delivery. The driver then returns to the vehicle and re-docks the device in its charging cradle. For a delivery driver, this procedure may be repeated 30 or more times per day.

Existing charging docks comprise a USB or other plug-type connector that engages with a complementary socket of the device. The plug-type connector usually comprises a number of electrodes that connect with internal electrodes of the device, to provide power and/or data connections between the dock and the device.

Alternatively, a simple power and/or data cable may be used to charge or otherwise connect the device to the vehicle's systems or power supply. For example, a cigarette lighter charging cable is often used to recharge portable electronic devices in vehicles.

Repeated connection and disconnection of the plug and socket inevitably leads to wear of the electrodes, and/or if the device is not correctly aligned with the plug during connection/disconnection, mechanical damage, fatigue or breakage of the plug or socket can occur.

Failure of the data and/or power socket of the portable electronic device is one of the most common forms of damage to portable electronic devices such as mobile telephones, tablet computers POD devices and the like.

Further, because different people use different makes and models of portable devices, it is difficult to manufacture, produce and/or provide a universal dock in, say, a vehicle, which can fit all types of devices due to the differences in size, button locations, charging socket positions etc.

A need therefore exists for a solution to one or more of the above problems.

According to the invention, there is provided a case for a portable electronic device comprising a main body portion having a hollow receiving portion adapted, in use, to releasably receive, and engage with, the exterior of a portable electronic device, the main body portion comprising a plug connector adapted to engage with a power and/or data port of the portable electronic device and a contact pad located on an exterior surface of the case.

Suitably, the case is manufactured from a polymeric material. Suitably, the polymeric material is resiliently deformable and/or rubberised to provide impact protection for the device, in use, and/or to enable the cast to be stretch-fitted over the device. The case may, in certain embodiments of the invention, be manufactured from silicone rubber, polyurethane, polyvinylchloride or other similar materials.

The hollow receiving portion has a shape and dimensions that substantially match those of the device. Cut-outs, apertures and other formations may be provided in the case that register with buttons of the device, a headphone jack of the device, a camera lens of the device a flash bulb of the device etc. Suitably, the hollow receiving portion comprises a resiliently deformable, overhanging lip or rebate, which partially wraps around the portable electronic device to releasably retain it within the hollow receiving portion. Suitably, the portable electronic device can be removed from the case by deforming the case, e.g. peeling back the overhang or rebate of the case to release the device.

The main body portion comprises a plug connector, which is suitably formed in, an arranged to project into the hollow receiving portion. The plug connector is arranged to register with the charging/data socket of the device. The plug connector may be of any suitable type, but it will be appreciated that likely candidates include, but are not limited to, a USB plug, a mini USB plug, a micro USB plug, a headphone-type charging plug, or a proprietary plug, such as an iPhone® lightening plug.

The plug connector comprises electrodes that make electrical connections with corresponding electrodes, in use, of the device. The electrodes provide power and/or data connections between the device and the plug connector.

The plug connector is operatively connected to the contact pad, for example by wires that may be moulded into the main body portion. A circuit board may be interposed between the plug connector and the contact pad, for example, for controlling or conditioning the power going into the device and/or for processing data. The circuit board, where provided, may comprise a charging circuit and/or means for preventing power surges to the portable electronic device. This may be particularly useful where the invention is used in a motor vehicle whereby the available power source, e.g. a 12V DC battery, may not provide a smooth, continuous voltage and/or current.

The contact pad suitably comprises a set of substantially planar contact pads, which are arranged to make contact with correspondingly positioned electrodes of a dock for the case. The correspondingly positioned electrodes of the dock may be formed from bent-over wires or resiliently deformable (e.g. sprung) contacts that make electrical connections with the contacts of the contact pad.

A dock may additionally be provided that connects to the case. The dock suitably comprises formations for receiving the case, for example, a recess into which the case clips or engages. Additionally or alternatively, the case and dock may comprise specially-adapted formations, such as lugs and grooves, that inter-engage to retain the case in the dock. The lugs and grooves may be resiliently deformable so that the case clips into, or otherwise positively engages with the dock. This may be particularly useful where the invention is used in a motor vehicle, which often vibrates or bounces around: positive engagement reducing the likelihood of inadvertent disconnection of the case from the dock.

The dock, where provided, comprises a complementary contact pad comprising resiliently deformable electrodes that are arranged to make electrical connections with the electrodes of the case's contact pad when the two are fastened or clipped together. The dock may additionally comprise a formation for engaging a dashboard clip of a vehicle.

A second aspect of the invention provides a dock adapted to receive, and form electrical connections with, the case as herein described.

The invention overcomes the problems outlined above by providing a case that forms an electrical connection with the socket of the device. This connection only needs to be connected or disconnected occasionally, i.e. when the device is inserted in, or removed from the case. As the portable electronic device will rarely be removed from its (protective) case, the likelihood of wear, fatigue and breakage of the device's socket connector is reduced. However, the case and device together can be repeatedly clipped into and out of the dock, and because the contact pads of the case and dock are of a durable construction, that is to say, designed to withstand repeated connection and disconnection, the case thus ruggedizes the device in a manner that reduces the likelihood of the damage thereto. Suitably, the case is disposable, such that if/when the contact pad becomes damaged, it can be discarded and the case replaced. The invention also overcomes the problem of interoperability of different devices with common docks: provided the contact pad of the case is provided in a uniform position, and provided the case has formations that connect to the dock, all that needs to be changed to make any device connect to the dock is the shape and configuration of the case's hollow receiving portion and/or the location and/or type of plug connector of the case.

### BRIEF DESCRIPTION OF THE DRAWINGS

Preferred embodiments of the invention shall now be described, by way of example, only, with reference to the accompanying drawings in which:

FIG. 1 is a perspective view of the underside of a first case in accordance with the invention;

FIG. 2 is a perspective view of the top of the case of FIG. 1 with a mobile telephone partially inserted therein;

FIG. 3 is a perspective view of the case and mobile telephone of FIG. 2 ready for insertion into a dock; and

FIG. 4 is a perspective view of a perspective view of a second embodiment of a case and dock in accordance with the invention.

### DETAILED DESCRIPTION

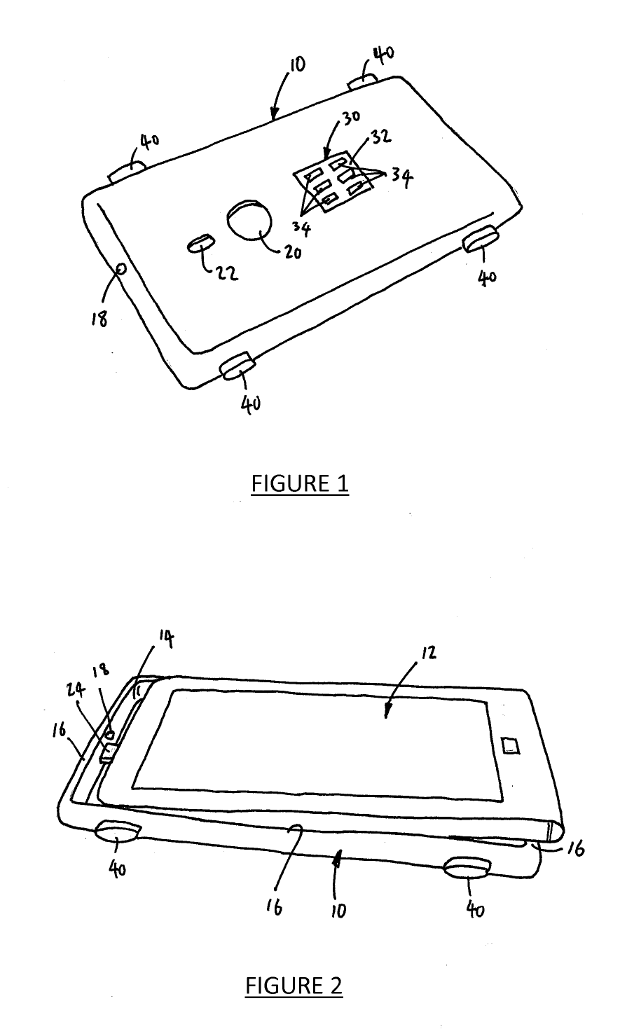

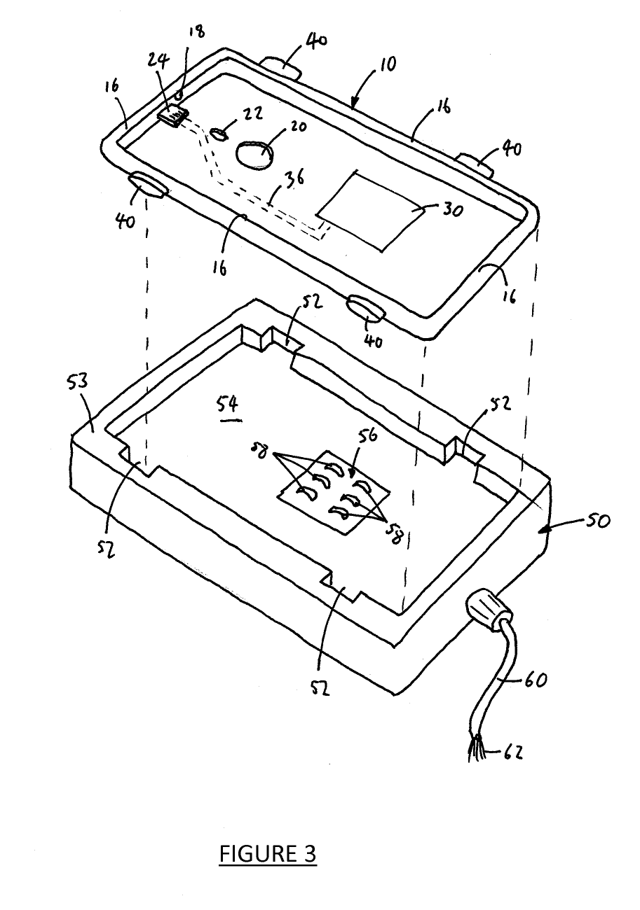

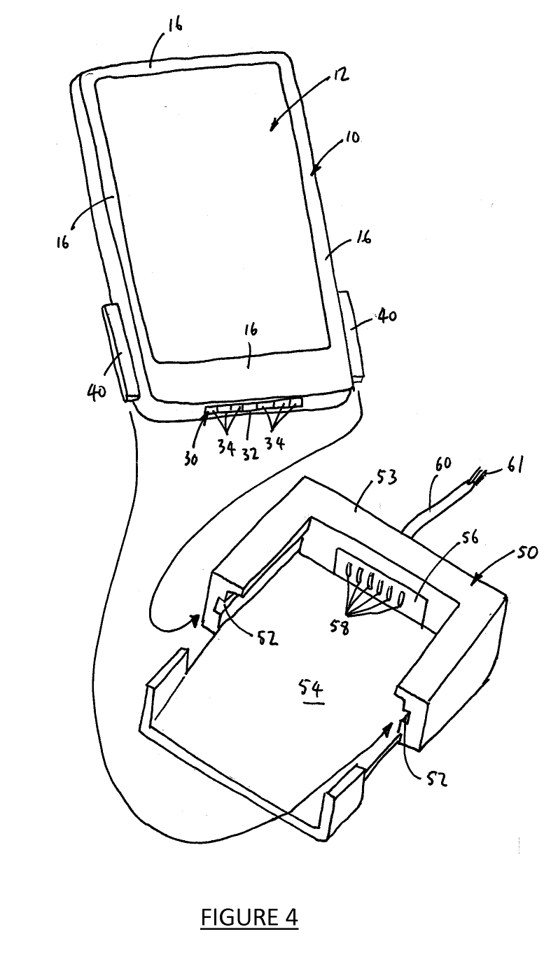

In FIGS. 1 and 2, a case 10 in accordance with the invention comprises an elastomeric “skin” type cover for a mobile telephone 12 manufactured from a polymeric material, such as PP, PE or silicone rubber. The case 10 comprises a hollow receiving portion 14 in the form of a cavity bounded by a peripheral lip portion 16 that overhangs the hollow receiving portion 14 slightly. As can be seen in FIGS. 2 and 3, a mobile telephone 12 can be inserted into the hollow receiving portion 14 by bending the peripheral lip portion 16 back slightly and by pushing it into position. When correctly seated in the hollow receiving portion 14, the peripheral lip 16 contracts around the edge of the phone 12 to hold it in place. The case 10 comprises a number of through apertures 18, 20, 22 that correspond, and register with, the headphone jack, camera lens and flash bulb of the phone respectively. More or fewer such apertures may be provided, and their shapes and configurations will naturally be dictated by the shape and configuration of the phone's features.

The interior of the case 10 comprises an integrally formed plug 24 that slides into, and engages with the power/data socket (not visible) of the phone 12. The plug 24 can be inserted into the socket, as shown in FIG. 2, by virtue of the resilience of the case 10 and by sliding the phone 12 into the case 10 at an angle so that the plug 24 engages with the phones socket (not visible) prior to complete insertion of the phone 12 into the case 10.

The underside of the case 10 can be seen in FIG. 1, and this has a contact pad 30 on it. The contact pad 30 comprises a main body portion in the form of a flat plastics plate 32, and a plurality of surface contact electrodes 34 that correspond with the electrodes of the plug 24. The electrodes of the contact pad 30 are electrically connected to respective electrodes of the plug connector 24 by a ribbon cable 36 that is moulded into the wall of the case 10. Thus, the contact pad 30 provides electrical connections to the phone 12 when the phone has been inserted into the case 10.

The case 10 additionally comprises projecting lugs 40 that project outwardly from the case, and which engage with complementary recesses 52 of a dock 50, as shown in FIG. 3. The dock 50 comprises a main body portion 55 having a hollow receiving portion 54 that receives the case 10 in a push-fitting manner. The lugs 40 engage with the recesses 52 of the dock 50 to secure the two together.

The dock 50 comprises a contact pad 56, which comprises a plurality of resiliently deformable electrodes 58 that are arranged to register with the surface contact electrodes 34 of the case's contact pad 30. The dock 50 further comprises a multi-core data/power cable fly-lead 60 that comprises wires 62 that electrically connect to each of the resiliently deformable electrodes 58. Thus, when the case 10 and phone 12 are correctly inserted into the dock 50, electrical connections of the phone are connected to the corresponding cores of the fly lead 60.

The second embodiment of the invention, as shown in FIG. 4 is substantially the same as that described above in relation to FIGS. 1 to 3 and identical reference signs have been used to identify identical features to avoid unnecessary repetition.

The embodiment of FIG. 4 comprises a skin-type case 10 for a portable electronic device 12 in which the contact pad 30 is located on an end of the case 10, rather than on its underside, as described above. The case 10 comprises two elongate projections 40 that engage with slots 52 of the dock 50 when the case 10 (and device 12) is inserted longitudinally into the dock 50. The dock 50 comprises a corresponding contact plate 56 with resiliently deformable electrodes 58 arranged to make respective electrical connections with the contact surfaces 34 of the case's contact pad 30. In the embodiment of FIG. 4, the dock 50 is in the form of a “cradle” that the device 12 can be dropped into.

The invention therefore enables a range of devices to be ruggedized and connected to a common dock. The invention has been described in relation to a mobile telephone, although it will be appreciated that the invention is equally applicable to other types of portable electronic devices as well, such as POD devices, point of sale (POS) terminals, laptop computers, tablet computers and the like.

1. A case for a portable electronic device, the case comprising:
a main body portion having a hollow receiving portion adapted, in use, to releasably receive, and engage with, an exterior of the portable electronic device, the main body portion comprising
a plug connector adapted, in use, to engage with a power and/or data port of the portable electronic device, and
a contact pad located on an exterior surface of the case.

2. The case of claim 1, wherein the contact pad comprises a set of substantially planar contacts.

3. The case of claim 2, wherein the contact pad further comprises a contact pad main body portion and wherein the contacts comprise a plurality of surface contact electrodes each corresponding, and being electrically connected, to a respective electrode of the plug connector.

4. The case of claim 1, wherein the plug connector is formed in, and is arranged to project into, the hollow receiving portion and wherein the plug connector is arranged, in use, to register with the power and/or data port of the portable electronic device when the portable electronic device is located in the hollow receiving portion.

5. The case of claim 1, wherein the plug connector comprises any one or more of the group comprising: a USB plug; a mini USB plug; a micro USB plug; a headphone-type charging plug; a proprietary plug; and an Apple iPhone lightening plug.

6. The case of claim 1, wherein the plug connector is operatively connected to the contact pad by wires that are moulded into the main body portion of the case.

7. The case of claim 6, wherein the wires are a ribbon cable and the contact pad has electrodes that are electrically connected to respective electrodes of the plug connector by the ribbon cable.

8. The case of claim 1, further comprising a circuit board interposed between the plug connector and the contact pad.

9. The case of claim 8, wherein the circuit board comprises power conditioning circuit.

10. The case of claim 8, wherein the circuit board comprises a data processing circuit.

11. The case of claim 1, wherein the main body portion is manufactured from any one or more of the group comprising: a polymeric material; a resiliently deformable material; a rubberised material; an elastomer; silicone rubber;
polyurethane; polyethylene; polypropylene; and polyvinylchloride.

12. The case of claim 1, wherein the hollow receiving portion comprises an aperture adapted to register with any one or more of the group comprising: a button of the device; a headphone jack of the device; a camera lens of the device; and screen of the device; and a flash bulb of the device.

13. The case of claim 1, wherein the hollow receiving portion comprises a resiliently deformable, overhanging lip adapted, in use, to at least partially wrap around the portable electronic device to releasably retain it within the hollow receiving portion.

14. A docking system for a portable electronic device comprising the case of claim 1 and a dock adapted to receive the case, the dock comprising dock electrode arranged, in use, to make an electrical connection with a contact of the contact pad of the case when the case is located in the dock.

15. The docking system of claim 14, wherein the dock electrode comprises a sprung contact.

16. The docking system of claim 14, wherein the dock comprises a complementary contact pad comprising a set of resiliently deformable dock electrodes that are arranged to make electrical connections with a respective set of contacts of the case's contact pad when the case is located in the dock.

17. The docking system of claim 16, wherein the dock further comprises a multi-core data/power cable fly-lead that comprises wires that electrically connect to each of the resiliently deformable dock electrodes such that when the case and portable electronic device are correctly inserted into the dock, electrical connections of the portable electronic device are connected to the corresponding wires of the fly lead.

18. The docking system of claim 14, wherein the dock comprises formations for receiving the case, the formations comprising any one or more of the group comprising: a recess into which the case clips or engages; a lug arranged to cooperate with a groove of the case; and a groove arranged to cooperate with a lug of the case.

19. The docking system of any of claim 14, wherein the dock comprises a connector for connecting, in use, the dock to a dashboard of a vehicle.

20. The case of claim 1, wherein the portable electronic device comprises any one or more of the group comprising: a mobile telephone; a point of delivery device; a point of sale terminal; a laptop computer; and a tablet computer.
